(19) United States
(12) Patent Application Publication
(10) Pub. No.: US 2020/0333858 A1
(43) Pub. Date: Oct. 22, 2020

(54) HEAT DISSIPATION DEVICE AND SYSTEM USING THE SAME

(71) Applicant: HONGFUJIN PRECISION ELECTRONICS (TIANJIN) CO.,LTD., Tianjin (CN)

(72) Inventors: TZE-CHERN MAO, New Taipei (TW); YEN-CHUN FU, New Taipei (TW); CHIH-HUNG CHANG, New Taipei (TW); YAO-TING CHANG, New Taipei (TW); CHAO-KE WEI, New Taipei (TW)

(21) Appl. No.: 16/407,485

(22) Filed: May 9, 2019

(30) Foreign Application Priority Data
Apr. 17, 2019 (CN) 201910310059.3

(51) Int. Cl. G06F 1/20; H05K 7/20

(52) U.S. Cl. CPC G06F 1/20; H05K 7/20263; H05K 7/20236; H05K 7/20818

(57) ABSTRACT

A self-compensating heat dissipating system able to adjust its own coolant level to take account of additions and removals of electronic devices in a heat dissipating device includes a plurality of the electronic devices. The heat dissipating device includes a refrigeration tank and a filling member, the refrigeration tank contains refrigerant. The electronic devices are installed inside of the refrigeration tank and submerged in the refrigerant. When one electronic device is taken out from or one electronic device is added to the refrigeration tank, the same effective immersed volume of the electronic device taken out or added is achieved by the filling member being added to or removed from the tank.

### FIELD

The subject matter herein generally relates to a heat dissipation system and system using the same.

### BACKGROUND

The need for computer data centers is increasing, and electronic devices such as servers are usually placed in a heat-absorbing pool or sink to dissipate heat. When electronic devices are removed or added into the sink, the liquid level of the coolant is changed.

Therefore, there is a room for improvement.

### BRIEF DESCRIPTION OF THE DRAWINGS

Implementations of the present disclosure will now be described, by way of embodiments, with reference to the attached figures.

FIG. 1 is a diagram of an embodiment of a heat dissipating system.

FIG. 2 is a diagram of another embodiment of the system of FIG. 1.

FIG. 3 is a diagram of another embodiment of the system of FIG. 1.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

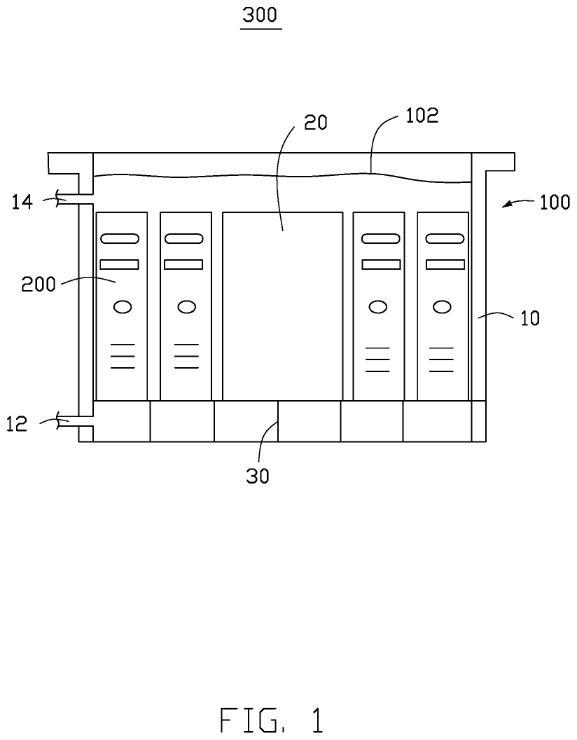

FIG. 1 illustrates a heat dissipation system 300 in accordance with an embodiment of the present disclosure.

The heat dissipation system 300 includes a heat dissipation device 100 and a plurality of electronic devices 200. The heat dissipation device 100 dissipates heat from the plurality of electronic devices 200.

In at least one embodiment, the heat dissipation device 100 includes a refrigeration tank 10 and a filling member 20. The refrigeration tank 10 contains refrigerant 102 and the plurality of electronic devices 200. The plurality of electronic devices 200 are installed inside of the refrigeration tank 10 and are submerged in the refrigerant 102.

The refrigerant 102 can enter inside of the plurality of electronic devices 200 through slots (not shown) on the plurality of electronic devices 200, to dissipate heat from the plurality of electronic devices 200.

The refrigeration tank 10 includes an inlet 12 and an outlet 14. The inlet 12 can be disposed at a lower portion of a sidewall of the refrigeration tank 10, and the outlet 14 can be disposed at an upper portion of the sidewall of the refrigeration tank 10.

The refrigerant 102 can enter the refrigeration tank 10 through the inlet 12, and can be discharged from the refrigeration tank 10 through the outlet 14.

The filling member 20 has the same volume as the electronic device 200 taken out in the refrigeration tank 10. When the electronic device 200 is removed from the refrigeration tank 10, the effective volume of the electronic device 200 removed from is replaced by the filling member 20, to maintain the liquid level of the refrigerant 102 in the refrigeration tank 10.

In at least one embodiment, the heat dissipation device 100 further includes a supporting member 30, and the supporting member 30 supports the plurality of electronic devices 200. The plurality of electronic devices 200 is not in direct contact with the bottom of the refrigeration tank 10, and the plurality of electronic devices 200 are located in an area between the inlet 12 and the outlet 14.

The refrigerant 102 first enters the inlet 12, and then into the refrigeration tank 10. The refrigerant 102 enters the plurality of electronic devices 200 through the bottom. The refrigerant 102 further flows out from the top of the plurality of electronic devices 200, and is then discharged from the refrigeration tank 10 through the outlet 14.

A flow loop of refrigerant 102 is thus obtained, through the inlet 12, the plurality of electronic devices 200, and the outlet 14, to enhance the heat absorbing or dissipating effect of the refrigerant 102.

In at least one embodiment, the supporting member 30 is disposed at the lower portion of the refrigeration tank 10, and the plurality of electronic devices 200 is placed on the supporting member 30.

The support member 30 abuts the inlet 12, and the refrigerant 102 can pass through the supporting member 30 and flow into the bases of the plurality of electronic devices 200.

In another embodiment, the supporting member 30 can be disposed on a sidewall of the refrigeration tank 10, and the plurality of electronic devices 200 can be suspended from the supporting member 30.

In at least one embodiment, the refrigerant 102 is a non-conductive insulating liquid. Therefore, the immersed electronic devices 200 are not short circuited.

In at least one embodiment, the electronic device 200 can be a server.

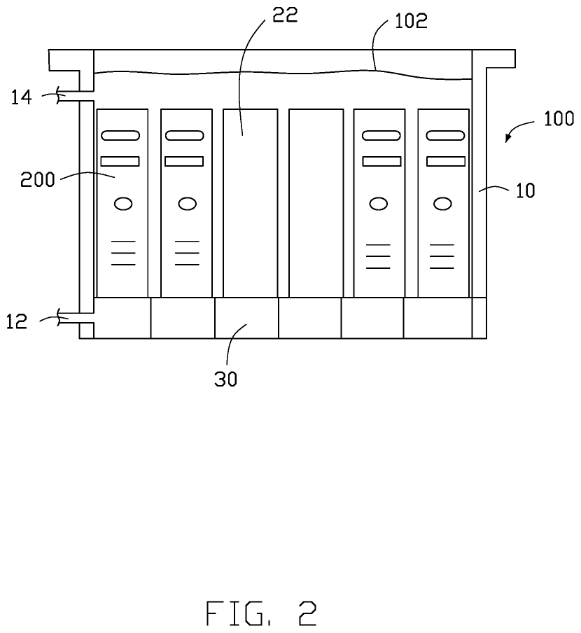

FIG. 2 illustrates that the filling member 20 further includes a plurality of fillers, and shapes and volumes of each of the fillers 22 are substantially the same as those of the electronic devices 200.

Each of the fillers 22 fills a vacant position after each of the electronic devices 200 is removed from the refrigeration tank 10 and the filler 22 has the same volume as an electronic device 200 which is removed from the refrigeration tank 10.

For example, when one electronic device 200 is removed from the refrigeration tank 10, one filler 22 will replace the electronic device 200, to fill the vacant position of the refrigeration tank 10. Therefore, when the electronic device 200 is removed from the refrigeration tank 10, the filler 22 can fill the vacant position of the refrigeration tank 10, and the filler 22 has the same volume as the electronic device 200 taken out from the refrigeration tank 10.

Therefore, the liquid level of the refrigerant 102 in the refrigeration tank 10 can be prevented from changing, thereby avoiding the problem of varying heat dissipation due to the liquid level of the refrigerant 102 being lowered.

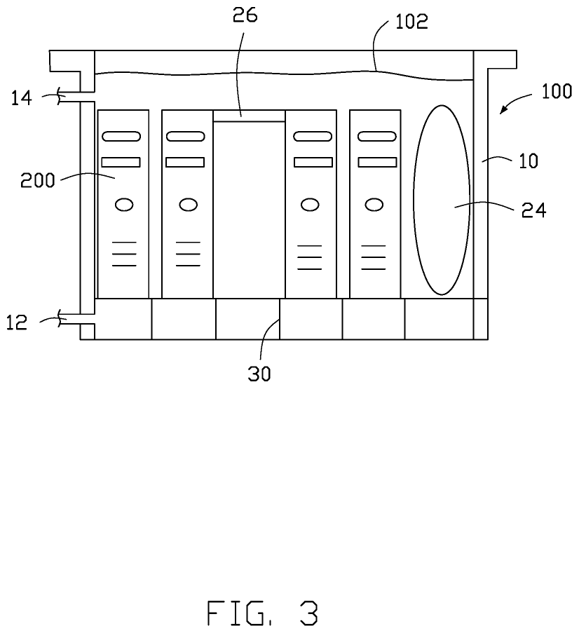

FIG. 3 illustrates a second embodiment of the filling member 20. The filling member 20 includes an expansion member 24 and a baffle board 26.

The expansion member 24 is disposed in the refrigeration tank 10 and immersed in the refrigerant 102. The expansion member 24 is connected to a control device (not shown) outside the refrigeration tank 10 through a vent pipe (not shown). The expansion member 24 can be expanded or reduced in volume under the control of the control device, so as to match the immersed volume of the electronic device 200 taken out from the refrigeration tank 10.

For example, when the electronic device 200 is removed from the refrigeration tank 10, the expansion member 24 will be expanded correspondingly to have the same volume as the electronic device 200. Therefore, an additional amount of refrigerant 102 is not required in the refrigeration tank 10 to maintain the liquid level of the refrigeration tank 10.

When a device 200 is to be added, the expansion member 24 will be correspondingly reduced to reduce the immersed volume. Therefore, the refrigerant 102 will not overflow from the refrigeration tank 10.

In at least one embodiment, the baffle board 26 is disposed at the vacant position after the electronic device 200 is removed from the refrigeration tank 10. The baffle board 26 prevents the refrigerant 102 from forming a short circuit, that is, is prevented from forming a flow loop through the inlet 12, the vacant position, and the outlet 14.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A heat dissipation device comprising:
a filling member; and
a refrigeration tank containing refrigerant,
wherein the refrigeration tank is configured to install a plurality of electronic devices there within and submerge the electronic devices in the refrigerant, and
wherein a volume of the filling member fills into the refrigeration tanks when the electronic device is removed from the refrigeration tank, the volume of the filling member being same as a volume of the electronic device being removed.

2. The heat dissipation device of claim 1, wherein the refrigeration tank comprises an inlet, the refrigerant fills into the refrigeration tank through the inlet.

3. The heat dissipation device of claim 2, wherein the refrigeration tank further comprises an outlet, the refrigerant is discharged from the refrigeration tank through the outlet.

4. The heat dissipation device of claim 3, wherein the heat dissipation device further comprises a supporting member, and the supporting member is configured to support the plurality of electronic devices.

5. The heat dissipation device of claim 4, wherein the supporting member is disposed at a lower portion of the refrigeration tank, and the plurality of electronic devices are disposed on the supporting member.

6. The heat dissipation device of claim 1, wherein the refrigerant is non-conductive insulating liquid.

7. The heat dissipation device of claim 1, wherein the filling member further comprises a plurality of fillers, and a shape and a volume of each of the fillers are substantially the same as a shape and a volume of a corresponding one electronic device.

8. The heat dissipation device of claim 7, wherein the filler fills a vacant position vacated by the electronic device removed from the refrigeration tank, and fills the same volume as the electronic device which is removed from the refrigeration tank.

9. The heat dissipation device of claim 1, wherein the filling member comprises an expansion member, the expansion member is disposed in the refrigeration tank and immersed in the refrigerant, and the expansion member is expanded or reduced in volume to match a drainage volume caused by the electronic device being removed from the refrigeration tank.

10. The heat dissipation device of claim 9, wherein the filling member further comprises a baffle board, the baffle board is disposed at a vacant position vacated by the electronic device being removed from the refrigeration tank.

11. A heat dissipation system, comprising:
a plurality of electronic devices; and
a heat dissipation device comprising:
a filling member; and
a refrigeration tank containing refrigerant,
wherein the refrigeration tank is configured to install the plurality of electronic devices there within and submerge the electronic devices in the refrigerant, and
wherein a volume of the filling member fills into the refrigeration tanks when the electronic device is removed from the refrigeration tank, the volume of the filling member being same as a volume of the electronic device being removed.

12. The heat dissipation device of claim 11, wherein the refrigeration tank comprises an inlet, the refrigerant fills into the refrigeration tank through the inlet.

13. The heat dissipation device of claim 12, wherein the refrigeration tank further comprises an outlet, the refrigerant is discharged from the refrigeration tank through the outlet.

14. The heat dissipation device of claim 13, wherein the heat dissipation device further comprises a supporting member, and the supporting member is configured to support the plurality of electronic devices.

15. The heat dissipation device of claim 14, wherein the supporting member is disposed at a lower portion of the refrigeration tank, and the plurality of electronic devices are disposed on the supporting member.

16. The heat dissipation device of claim 11, wherein the refrigerant is non-conductive insulating liquid, and the electronic device is a server.

17. The heat dissipation device of claim 11, wherein the filling member further comprises a plurality of fillers, and a shape and a volume of each of the fillers are substantially the same as a shape and a volume of a corresponding one electronic device.

18. The heat dissipation device of claim 17, wherein the filler fills a vacant position vacated by the electronic device removed from the refrigeration tank, and fills the same volume as the electronic device which is removed from the refrigeration tank.

19. The heat dissipation device of claim 11, wherein the filling member comprises an expansion member, the expansion member is disposed in the refrigeration tank and immersed in the refrigerant, and the expansion member is expanded or reduced in volume to match a drainage volume caused by the electronic device being removed from the refrigeration tank.

20. The heat dissipation device of claim 19, wherein the filling member further comprises a baffle board, the baffle board is disposed at a vacant position vacated by the electronic device being removed from the refrigeration tank.
